(19) United States
(12) Patent Application Publication
(10) Pub. No.: US 2011/0116216 A1
(43) Pub. Date: May 19, 2011

(54) ELECTRONIC DEVICE

(76) Inventor: Chao-Chin Weng, TAIPEI CITY (TW)

(21) Appl. No.: 12/906,139

(22) Filed: Oct. 18, 2010

(30) Foreign Application Priority Data
Nov. 16, 2009 (TW) 098138756

(51) Int. Cl. H05K 7/00

(52) U.S. Cl. 361/679.01

(57) ABSTRACT

An electronic device includes a casing and a cover. The casing includes an opening, and a protrudent element protrudes inwardly from an inner wall of the casing. The cover is pivotally connected with the casing, and the cover is rotated to a closed position for covering the opening or to an open position for uncovering the opening. The cover has an extending portion extending towards an interior of the casing, and the extending portion is against the protrudent element when the cover is rotated from the closed position to the open position.

### CROSS-REFERENCE TO RELATED APPLICATIONS

This Non-provisional application claims priority under 35 U.S.C. §119(a) on Patent Application No(s). 098138756 filed in Taiwan, Republic of China on Nov. 16, 2009, the entire contents of which are hereby incorporated by reference.

### BACKGROUND OF THE INVENTION

1. Field of the Invention

This invention relates to an electronic device and, more particularly, to an electronic device capable of being positioned for covering.

2. Description of the Related Art

With development of technology, electronic devices have gradually become necessary daily living articles. Therefore, more and more peripheral products are developed and used. At the same time, application of the peripheral products in the electronic devices becomes a new trend of the current electronic devices.

Therefore, most of the current electronic devices on a market include a plurality of external connecting ports, such that the electronic devices can be connected with other peripheral products for use. When the connecting ports are not connected with the peripheral products, usually covering devices may cover the connecting ports for preventing dust or other dirt from entering thus to prevent pollution from damaging the connecting ports and to prevent poor contact of the connecting ports from failing to recognize connection of the peripheral products.

However, the current covering devices of the electronic devices on the market are easy to be loosened in use, such that the covering devices cannot be closed tightly. Furthermore, the common covering devices have imprecise positioning problems. That is, the covering devices cannot precisely cover the connecting ports when the covering devices are closed, and the covering devices may be easily damaged and loosened caused by exerting improper force.

### BRIEF SUMMARY OF THE INVENTION

This invention provides an electronic device including a casing and a cover. The casing includes an opening, and a protrudent element protrudes inwardly from an inner wall of the casing. The cover is pivotally connected with the casing, and the cover is rotated to a closed position for covering the opening or to an open position for uncovering the opening. The cover has an extending portion extending towards an interior of the casing, and the extending portion is against the protrudent element when the cover is rotated from the closed position to the open position.

In one preferred embodiment of the invention, a first pivotal portion may be further disposed at the inner wall of the casing, and the cover may be pivotally connected with the casing via the first pivotal portion. The cover may further include a covering portion and a second pivotal portion. The covering portion corresponds to the opening to cover the opening when the cover is in the closed position. The second pivotal portion is disposed between the covering portion and the extending portion. The cover is pivotally connected with the first pivotal portion of the casing via the second pivotal portion.

According to the electronic device in the invention, the cover can achieve a positioning effect when the cover is rotated from the closed position to the open position via the protrudent element protruding from the inner wall of the casing. Thereby, the cover not only can precisely cover objects which need to be protected but also can be prevented from being damaged, loosened, or positioned ineffectively in the prior art caused by exerting improper force in use.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a whole structure of an electronic device according to one embodiment of the invention;

FIG. 2 is a first sectional diagram showing a casing according to one embodiment of the invention;

FIG. 3 is a second sectional diagram showing a casing according to one embodiment of the invention;

FIG. 4 is a three-dimensional diagram showing a cover according to one embodiment of the invention;

FIG. 5 is a side view showing a cover which is opened according to one embodiment of the invention; and

FIG. 6 is a side view showing a cover which is closed according to one embodiment of the invention.

### DETAILED DESCRIPTION OF THE INVENTION

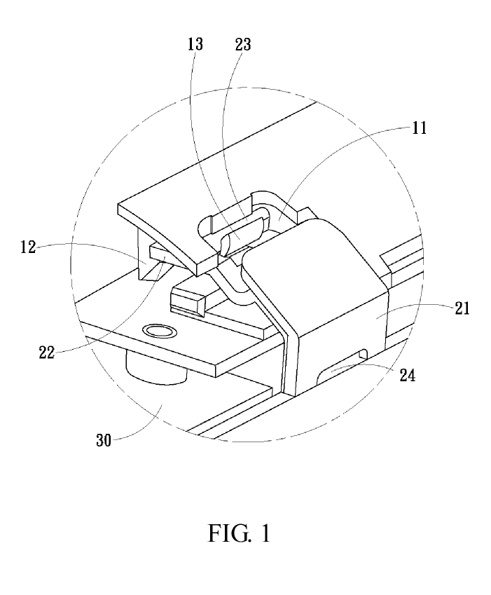

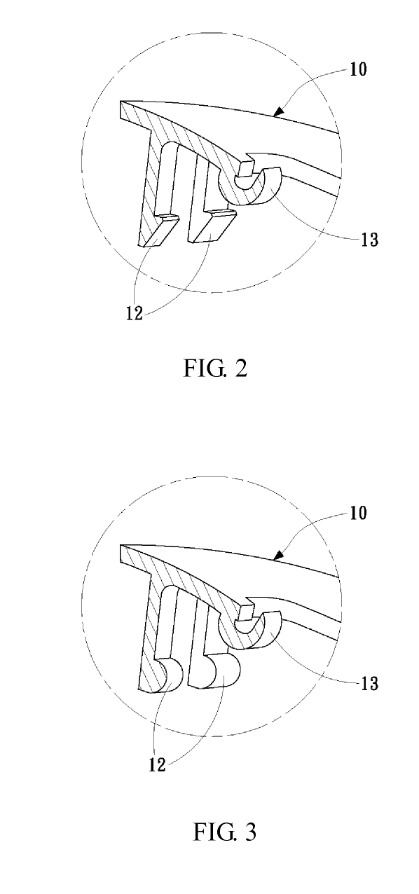

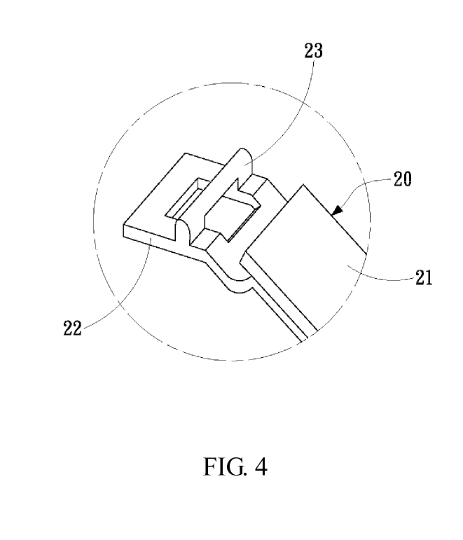

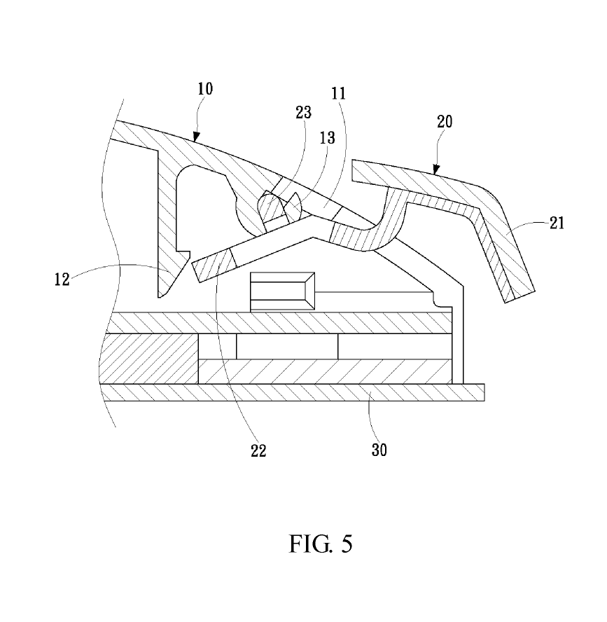

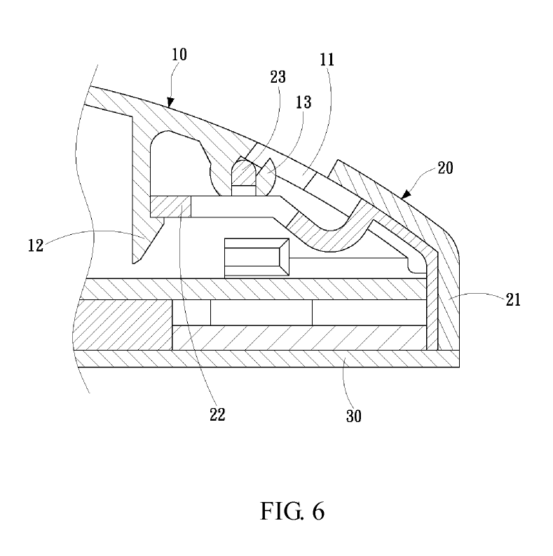

Please refer to FIG. 1 to FIG. 6 together. FIG. 1 is a schematic diagram showing a whole structure of an electronic device according to one embodiment of the invention. FIG. 2 is a first sectional diagram showing a casing according to one embodiment of the invention. FIG. 3 is a second sectional diagram showing a casing according to one embodiment of the invention. FIG. 4 is a three-dimensional diagram showing a cover according to one embodiment of the invention. FIG. 5 is a side view showing a cover which is opened according to one embodiment of the invention. FIG. 6 is a side view showing a cover which is closed according to one embodiment of the invention. An electronic device 30 in the embodiment of the invention includes a casing 10 and a cover 20.

In FIG. 2, the casing 10 includes an opening 11, and the opening 11 can expose components installed inside the electronic device 30. The shape of the casing 10 in FIG. 2 is just taken for example. The casing 10 may have other shapes according to internal structures of the electronic device 30.

In FIG. 2 and FIG. 3, a protrudent element 12 protrudes inwardly from an inner wall of the casing 10. In one preferred embodiment, the protrudent element 12 may be a square bar and may be an elastic structure made of plastic or other elastic materials. However, both the appearance and material of the protrudent element 12 are not limited thereto.

In addition, in FIG. 2, a size of one end of the protrudent element 12 is greater than that of other parts of the protrudent element 12. In one preferred embodiment, the protrudent element 12 may be a hook. However, the invention is not limited thereto. The protrudent element 12 may further be a protrudent portion, and via a curved surface of the protrudent portion, the surface of the protrudent element 12 may be easier for fastening and sliding, as shown in FIG. 3.

In FIG. 2, a first pivotal portion 13 is further disposed at the inner wall of the casing 10. In one preferred embodiment, the first pivotal portion 13 may be disposed adjacent to the opening 11. However, the invention is not limited thereto. In one preferred embodiment, the first pivotal portion 13 may be a hook-shaped pivotal base. However, the invention is not limited thereto.

In FIG. 1 and FIG. 4, the cover 20 is pivotally connected with the casing 10, and the cover 20 is rotated to a closed position for covering the opening 11 or to an open position for uncovering the opening 11. The cover 20 has an extending portion 22, and the extending portion 22 extends inwardly towards an interior of the casing 10.

In addition, the cover 20 further includes a covering portion 21 and a second pivotal portion 23. The shape of the covering portion 21 can conform to that of the opening 11, such that the covering portion 21 corresponds to the opening 11 to cover the opening 11 when the cover 20 is in the closed position. In one preferred embodiment, one end of the extending portion 22 may be a semi-circular extending structure, and the extending portion 22 may be connected with the covering portion 21 via the semi-circular extending structure of the extending portion 22. Then, the second pivotal portion 23 is disposed between the covering portion 21 and the extending portion 22 as shown in FIG. 4. The second pivotal portion 23 in this embodiment can preferably be a pivotal shaft. Further, in one preferred embodiment, the covering portion 21, the extending portion 22, and the second pivotal portion 23 may be integrally formed.

In addition, the cover 20 further includes a force exerted portion 24 at a side edge of the cover 20. In one preferred embodiment, the force exerted portion 24 may be located at a side edge of the covering portion 21. However, the invention is not limited thereto. The force exerted portion 24 can preferably be a slot. However, the invention is not limited thereto, and the force exerted portion 24 may further be a protrudent bar.

In FIG. 5 and FIG. 6, in the embodiment, the cover 20 is pivotally connected with the first pivotal portion 13 of the casing 10 via the second pivotal portion 23, allowing the cover 20 to be pivotally connected with the casing 10. Thereby, when the cover 20 is pivotally connected with the casing 10 and the cover 20 is rotated from the closed position to the open position, the extending portion 22 is against the protrudent element 12. Since the covering portion 21 and the extending portion 22 are preferably integrally formed, when the extending portion 22 and the protrudent element 12 are against with each other, the covering portion 21 can generate a click effect between the closed position and the open position.

According to the above, when a user is to open the cover 20, the user exerts force on the force exerted portion 24 to open the covering portion 21, allowing the cover 20 to be rotated from the closed position to the open position. At the same time, the extending portion 22 is driven to be against the protrudent element 12 and to allow the protrudent element 12 to be elastically deformed. Then, the extending portion 22 slides over the protrudent element 12, such that the user can clearly feel the click and a positioning effect is achieved. On the other hand, when the user is to cover the cover 20 at the opening 11, the user similarly exerts force on the force exerted portion 24 and pushes the covering portion 21 towards the opening 11 thus to drive the extending portion 22 to be against the protrudent element 12 again and to allow the protrudent element 12 to be elastically deformed. Thereby, the extending portion 22 slides over the protrudent element 12. Similarly, the user can feel the click, and the positioning effect is achieved.

According to the embodiment of the invention, via the interference between the protrudent element of the casing and the extending portion of the cover, the click is generated, and the positioning effect is achieved, such that when the cover is rotated from the closed position to the open position, the fastening and positioning effect can be achieved. Further, via the hook, the cover is no more loosened easily when the cover covers the opening, such that the whole structure can be more firm thus to achieve the more sufficient protection function.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic device comprising:
a casing including an opening, a protrudent element protruding inwardly from an inner wall of the casing; and
a cover pivotally connected with the casing, the cover being rotated to a closed position for covering the opening or to an open position for uncovering the opening;
wherein the cover has an extending portion extending towards an interior of the casing, and the extending portion is against the protrudent element when the cover is rotated from the closed position to the open position.

2. The electronic device according to claim 1, wherein a first pivotal portion is further disposed at the inner wall of the casing, and the cover is pivotally connected with the casing via the first pivotal portion.

3. The electronic device according to claim 2, wherein the cover further comprises a covering portion and a second pivotal portion, the covering portion corresponds to the opening to cover the opening when the cover is in the closed position, the second pivotal portion is disposed between the covering portion and the extending portion, and the cover is pivotally connected with the first pivotal portion of the casing via the second pivotal portion.

4. The electronic device according to claim 3, wherein the covering portion, the second pivotal portion, and the extending portion are integrally formed.

5. The electronic device according to claim 3, wherein the second pivotal portion of the cover is a pivotal shaft.

6. The electronic device according to claim 1, wherein a size of one end of the protrudent element is greater than that of other parts of the protrudent element.

7. The electronic device according to claim 6, wherein the end of the protrudent element comprises a hook, the extending portion of the cover is against the hook when the cover is rotated from the closed position to the open position.

8. The electronic device according to claim 1, wherein the cover further comprises a force exerted portion located at a side edge of the cover.

9. The electronic device according to claim 8, wherein the force exerted portion is a protrudent bar.

10. The electronic device according to claim 8, wherein the force exerted portion is a slot.
